(19) United States
(12) Patent Application Publication
(10) Pub. No.: US 2006/0049967 A1
(43) Pub. Date: Mar. 9, 2006

(54) Code driver for a memory controller

(76) Inventors: Andreas Jakobs, Munchen (DE); Peter Gregorius, Munchen (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/213,550

(22) Filed: Aug. 26, 2005

(30) Foreign Application Priority Data
Aug. 26, 2004 (DE) 10 2004 041 331.2

(51) Int. Cl. H03M 7/00

(52) U.S. Cl. 341/50

(57) ABSTRACT

A code driver is described having a codeword source, which has n>1 source terminals and is designed to output at these terminals a sequence of n-digit codewords, each in the form of n parallel code characters, and having n parallel transmission paths between the n source terminals and n transmit terminals for sending the message represented by the codewords to a receiver. According to the invention, a selection device is provided, which indicates explicitly for each codeword which of the n digits of the codeword concerned are relevant to the decoding of the message in the receiver, and which, dependent on this explicit indication, activates only those of the n transmission paths that are assigned to the relevant digits of the codeword.

### CROSS-REFERENCE TO RELATED APPLICATIONS

This application claims foreign priority benefits under 35 U.S.C. §119 to co-pending German patent application number DE 10 2004 041 331.2, filed 26 Aug. 2004. This related patent application is herein incorporated by reference in its entirety.

### BACKGROUND OF THE INVENTION

1. Field of the Invention

Embodiments of the invention relate to a code driver having a codeword source that is designed to provide a sequence of n-digit code words, each in the form of n parallel code characters. An application of the invention is a memory controller that contains the means for sending instruction and address information in addition to write data to a memory chip.

2. Description of the Related Art

In many cases, communication between electric circuit arrangements, e.g., between devices within a module or between different components of a system, occurs over a plurality of parallel lines. This allows digital coding of individual messages in parallel format, where each message is represented by a pattern of discrete and uniquely discriminatable signal states or levels on a plurality of lines. If “n” is the number of lines involved, then each pattern forms an n-digit “codeword” (also known as a “symbol”), where each line transfers one “character” of the codeword. The character repertoire “p” and hence the information value of a character equals the number of possible (discriminatable) signal states, and the information value of the whole codeword equals pⁿ. The p different possible signal states hence represent the p different digit values of a number system to base p e.g., the binary or logic values “0” and “1” of a binary number system in which p=2.

In order to separate consecutive codewords cleanly from each other and synchronize character transmission during continuous communication, the codeword sequence is usually generated and transmitted under clock control i.e., in each clock period, all n characters of an n-digit codeword are generated synchronously from a codeword source within the communications partner currently transmitting, and appear at n terminals of this source. Thus, a continuous sequence of n-digit codewords appears at the n source terminals throughout the transmit mode.

The larger the number of digits or “width” of the parallel-coded codewords and the higher the clock frequency, the greater the power used by the code driver. For each character to be transmitted, transmit power is consumed in order to take the electrical state of the transmit line concerned, right up to the receiver, to the level that reproduces uniquely the given character value. This power consumption is particularly large for each character change, because the charge may be transferred against the line reactance (usually mainly capacitive). The resulting high power consumption caused by the modulation of the transmit drivers causes the temperature to rise and the supply source to be depleted prematurely in the case of a battery or cell power supply.

### SUMMARY OF THE INVENTION

One embodiment of the invention provides reduced power consumption of a code driver of the type described above without reducing the number of digits of the codewords or the transmit speed.

One embodiment of the invention is implemented in a code driver containing a codeword source, which has n>1 source terminals and is designed to output at these terminals a sequence of n-digit codewords, each in the form of n parallel code characters, where n parallel transmission paths are provided between the n source terminals and n transmit terminals for sending the message represented by the codewords to a receiver. According to the invention, a selection device is also provided, which indicates explicitly for each codeword which of the n digits of the codeword concerned are relevant to the decoding of the message in the receiver, and which, dependent on this explicit indication, activates only those of the n transmission paths that are assigned to the relevant digits of the codeword.

Embodiments of the invention exploit the fact that not all the characters of the n-digit codeword are always relevant to the unique interpretation of a message by the receiver. Thus, it is often useful to assign a specific purpose in the receiver to selected subsets or groups of the lines within the n-line communication link and hence to selected digits of the n-digit codeword. It also happens that a message, which is assigned to a specific purpose and hence to a specific group of codeword digits, depending on its relevance, is either sufficient on its own or else requires an additional message that is accommodated in other digits of the codeword. In the latter case, the receiver takes account of the characters contained in these other digits, while in the former case it may ignore them (“don't care”).

For example, a first group of codeword digits can be assigned to the purpose of providing instructions for setting and holding one of a plurality of fundamental states of the receiver e.g., “idle state”, “configuration state” or “operating state”. A second group can be assigned to the purpose of supplying a message that defines specific parameters for the fundamental state to be set at that time e.g., the configuration setting in the case of the configuration state, or the operating speed setting in the case of the operating state. On the other hand, no further message elements are needed in conjunction with the “idle state” instruction; the characters of the second group are therefore irrelevant in this case, but are relevant in conjunction with the other two instructions. Furthermore, differences can also exist between these two instructions in terms of the number of characters that are needed to represent the respective parameters. For example, if the second group contains twelve digits, the configuration setting requires twelve characters, and if the operating speed setting requires just two characters, then ten characters of the second group are irrelevant in conjunction with the “operating state” instruction.

Put in general terms, the characters within selected groups of the n codeword digits can represent in full a message to be decoded or just a part of the whole message, and the respective pattern of these characters also implicitly (inherently) contains information as to whether and which of the remaining codeword digits are relevant to decoding the whole message and hence are not ignored. Thus, an explicit representation of this implicit “relevancy” information may be provided in the code driver to inhibit the forwarding of the currently “irrelevant” characters of the codeword supplied by the code source depending on this information.

Thus, embodiments of the invention prevent modulation of the transmit drivers by the currently “irrelevant” characters of a codeword that can be ignored during decoding in the receiver, thereby saving transmit power.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows as an extract a part of a memory controller having a code driver according to the invention;

FIG. 2 shows in a table a coding scheme for the control signals of a memory controller in connection with an explicit representation of the relevancy information according to one embodiment of the invention;

FIG. 3 shows a first embodiment of a transmission path between codeword source and transmit terminal of the code driver of FIG. 1; and

FIG. 4 shows a second embodiment of a transmission path between codeword source and transmit terminal of the code driver of FIG. 1;

### DETAILED DESCRIPTION OF THE PREFERRED EMBODIMENT

As described above, embodiments of the invention may be utilized in a memory controller where situations in which generated code characters can be ignored are very common. Thus, the example of the control-signal coding of a memory controller is used below to explain in greater detail the principle and particular embodiments of the invention with reference to drawings.

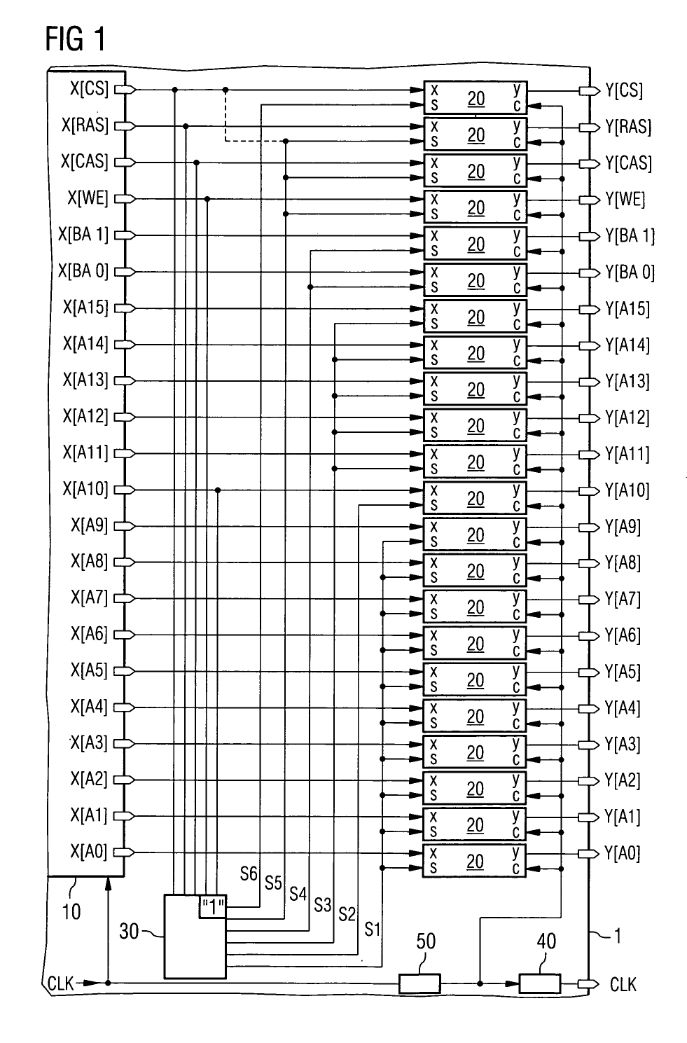

FIG. 1 shows an area of a memory controller 1 that contains the devices for generating and transmitting the control characters to one or more memory chips. The controller 1 may be integrated on a semiconductor chip and during operation is connected to each memory chip via a multiplicity of connecting lines constituting the communication lines.

The actual chip to be controlled in each case is not shown in the figure. In the example described here, the controller 1 is designed for communication with one or more synchronous dynamic RAM (SDRAM) memory chips of standard design, each integrated on a separate chip and containing a plurality of banks, each comprising a multiplicity of binary data storage locations that form in each bank a matrix of rows and columns. It shall be assumed for description purposes herein that the or each memory chip is of a size and organization such that two bank address bits, sixteen row address bits and eleven column address bits are used to select the storage locations for writing or reading data in a memory chip. In addition, it shall be assumed that (as is standard practice in typical SDRAMs) the row and column addresses are sent sequentially in time from the controller to the memory chip (first the row address and then the column address).

In addition to the address bits mentioned, the memory chip may require additional control signals, namely “instructions” for setting different operating states and for controlling operating procedures. Like the addresses, these instructions are generated in binary coded form. The instruction bits and the address bits are sent from the controller 1 in parallel format via an assigned bundle of connecting lines to the memory chip. Generation and transmission of the control signals are synchronized by a common clock signal CLK. FIG. 1 shows on the right edge of the controller 1 the assigned transmit terminals, labeled in the figure with capital Y, where the square brackets [ ] extension contains a short-form name for the assigned bits, which is used in the following description for identifying the bits. The controller 1 may also have a number of other terminals, which are used for transmitting and receiving the data and strobe signals to/from the memory chip and are not shown in FIG. 1. The clock signal CLK is also sent to the memory chip via a clock transmit amplifier 40.

The “contents” (character value) of the bits for the addresses and instructions, i.e., the respective binary value “0” or “1”, are updated within the controller 1 in each CLK clock period, so that with every clock pulse a special combination of n characters is generated, where n is the total number of instruction and address bits. This character combination thus forms in total an n-digit codeword in parallel format, and the device that generates the consecutive codewords thus constitutes a code source having n separate source terminals, one for each bit position of the codeword. The code source is shown in FIG. 1 by a block 10, and the source terminals are labeled with capital X, where again the short-form name of the bit position concerned is added in brackets. The n-digit source codewords of the n source terminals X are output on n parallel transmission paths each shown schematically by a block 20, and each of which has a transmit terminal Y assigned to its output.

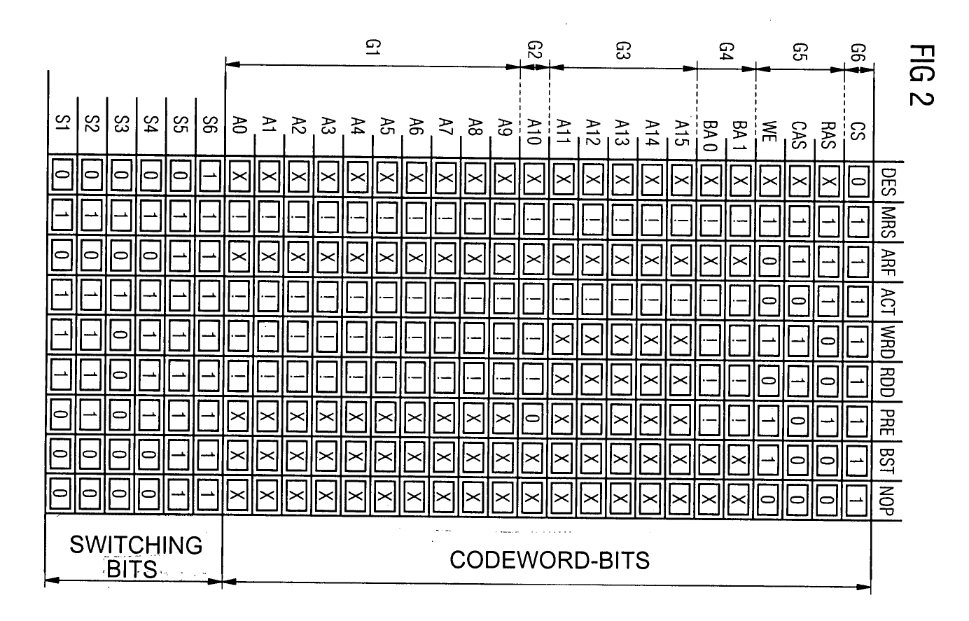

The instruction and address coding scheme used by the code source 10 in the example described here is the same as that currently in common use for controlling SDRAMs, and is shown in table form in the top section of FIG. 2. This table section contains n rows corresponding to the n bit positions of the codeword.

A first bit position CS (“Chip Select”) provides the instruction for the selection/deselection of the memory chip, where “1” means selection (operating state) and “0” deselection (idle state). Three additional bit positions, conventionally labeled (for historical reasons) as RAS, CAS and WE, are used for formulating eight (=2³) operating instructions. Two further bit positions BA0 and BA1 provide the address for the bank addressing at the memory chip, and sixteen additional bit positions A0 to A15 are provided for the row and column addressing. The full set of all sixteen address bits A0:A15 (the colon “:” stands for “to”) is used to formulate the row address, while eleven bits are sufficient to formulate the column address, as specified earlier in the document. Since simultaneous transmission of row address and column address is not intended, a subset of the bit positions A0:15 can also be used advantageously for the column address; in the present example these are the eleven bit positions A0:10.

In the n-row codeword table of FIG. 2, the bit positions are represented by rectangular boxes. Each row is, as stated, assigned to a bit position. Nine columns are shown in total, one for each of nine instructions whose names are entered in short-form in the column header. These instructions and the assigned bit patterns in the codeword are described below.

DES (Deselect) expressed by “0” in the bit position CS, i.e.

CS=0

instructs deselection (“no operation”). In this case, the contents of all other bit positions of the codeword are immaterial; these contents are consequently irrelevant and may be ignored. This is symbolized in the table by the entry “X” in the appropriate boxes.

MRS (Mode Register Set), expressed by

CS=1

RAS=1

CAS=1

WE=1

instructs the setting of operating parameters of the memory chip during an initialization phase. The information defining which parameters shall be set to which values is coded in the address bit positions B1, B2 and A0:15, because for the MRS instruction no storage locations are addressed. The contents (“0” or “1”) of these bit positions are thus relevant and not ignored, which is symbolized by the entry “!” in the appropriate boxes.

ARF (Autorefresh), expressed by

CS=1

RAS=1

CAS=1

WE=0

instructs the automatic refreshing of all storage locations in the memory chip. No addressing is required for this. Thus the contents of all address bit positions B1, B2 and A0:15 are irrelevant in this case (“X”).

ACT (Activate), expressed by

CS=1

RAS=1

CAS=0

WE=0

instructs the activation of a selected storage-location row in the memory chip for a write or read operation by applying an activation potential to the appropriate row-selection line, where this potential continues to be applied until a close instruction (PRE, see below) is given. All the address bits BA0, BA1 and A0:15 are required here for selecting the row; The contents of the associated bit positions are therefore relevant and not ignored (“!”).

WRD (Write Data), expressed by

CS=1

RAS=0

CAS=1

WE=1

instructs the writing of data in selected locations of the activated row by opening (make conducting) data paths for transferring the data bits applied to the data terminals of the chip to the locations concerned. In this case the address bits BA0, BA1 for selecting the memory bank and the eleven address bits A0:A10 for column selection are used for selecting the locations. Thus the contents of the associated bit positions are relevant and are not ignored (“!”). The contents of the remaining address bits A11:A15 are irrelevant (“X”).

RDD (Read Data), expressed by

CS=1

RAS=0

CAS=1

WE=0

instructs the reading of data from selected locations of the activated row by opening (make conducting) data paths for transferring the data from the locations concerned to the data terminals of the chip. In this case the address bits BA0, BA1 for selecting the memory bank and the eleven address bits A0:A10 for column selection are used for selecting the locations; Thus the contents of the associated bit positions are relevant and are not ignored (“!”). The contents of the remaining address bits A11:A15 are irrelevant (“X”).

PRE (Precharge), expressed by

CS=1

RAS=1

CAS=0

WE=1

and additionally

A10=0

instructs the “closing” of a bank, i.e., termination of the row activation, initiated with the instruction ACT, by applying a deactivation potential (“precharge” potential) to all row-selection lines of the bank selected with ACT. In this case only the bank address bits BA0, BA1 are relevant and are not ignored (“!”). The contents of the address bits A0:A15 are irrelevant (“X”).

If all the banks are to be instructed to close, then A10 can be set to “1” instead of “0” for the instruction PRE. BA0 and BA1 are irrelevant for this option. With the instruction PRE, any of the other address bits A0:A15 could also be used instead of A10.

BST (Burst Stop), expressed by

CS=1

RAS=0

CAS=0

WE=1

instructs the termination of a write or read cycle in progress. No specific addressing is required for this. Thus the contents of all address bit positions B1, B2 and A0:A15 are irrelevant in this case (“X”).

NOP (No Operation), expressed by

CS=1

RAS=0

CAS=0

WE=0

instructs that there is to be no change in the prevailing operating state. The contents of all other bit positions B1, B2 and A0:A15 are thus irrelevant in this case (“X”).

It is in the nature of a coder to output, while it is in operation, within each clock period and for each bit position of a codeword, a defined character, i.e., either “0” or “1” in the case of a binary coder, from which the codewords output by the codeword source 10 ultimately originate (the codeword source 10 can itself even be the n-bit coder). As mentioned above, a certain amount of energy is required to transmit each character from the transmitter terminals Y; this energy is considerable for each change in the character content.

In order to reduce the power consumption of the controller 1 (code driver), embodiment of the invention ensure that little transmit power is consumed for those characters that are output by the codeword source 10 according to the coding specification, but that are irrelevant in the memory chip (receiver) for interpreting the information contained in the codeword. Expressed the other way round, embodiments ensure that only the currently relevant characters modulate the transmit terminals Y.

For this purpose, a selection device 30 is provided in the controller 1 that ensures that the transmission paths 20 between the source terminals X of the codeword source 10 and the transmit terminals Y are selectively active or inactive for transmit modulation depending on whether the contents of the bit (character) assigned to the respectively assigned source terminal is relevant or irrelevant to the memory chip. The selection device 30 has a plurality of parallel output terminals, which are connected in a special pattern to switching signal inputs s of the transmission paths 20, and each output is a “switching bit” S, which activates or deactivates the transmission path 20 concerned depending on the binary value of the bit. The binary value “1” is intended to set the “active” state, and the binary value “0” is intended to set the “inactive” state.

In the example described here, the selection device 30 responds to bits from the X-terminals. It is basically a look-up table e.g., in the form of a read only memory (ROM), which receives as an address the bits of the source codewords at a plurality of address inputs, and for each address outputs a unique value combination for the switching bits S.

In one embodiment, a ROM suitable for the function of the selection device could have n address inputs and n switching-bit outputs S, and be designed so that it outputs in the switching bits S, for each pattern of the n source-codeword bits X, exactly that binary pattern that contains a “1” at the digits corresponding to the relevant bits of the X pattern and a “0” at the digits corresponding to the irrelevant bits of the X pattern. Such a ROM may have n selectively addressable memory locations each having n binary storage locations. In the present case of n=22, a ROM matrix having 484 binary storage locations may be provided. The ROM could be designed as a programmable ROM (“PROM”), which would have the advantage that it can be adapted to suit every type of coding scheme of the codewords and hence every type of instruction structure of a memory chip to be controlled.

In one embodiment, the selection device may have a simpler design, however, if one specializes its design by taking account of certain individual features of the specific coding scheme applied to the instruction and address bits used in the receiver. For instance, in the coding scheme chosen as the example here, one can see from FIG. 2 the following:
(a) In the complete set N of all n bits of the n-digit codeword there exists precisely one subset K of k elements able to give any information at all on the relevancy or irrelevancy of codeword bits.
(b) The set N can be divided into g<n groups G1 to Gg, where all of the elements in each of the groups can only be relevant simultaneously.

In the case illustrated, K contains the k=5 codeword bits CS, RAS, CAS, WE, A10. The number of groups is g=6. Consequently, just a 6-digit “switching-bit word” comprising the switching bits S1 to S6, each of which is assigned to one of the g groups G1 to G6, is sufficient for the selective activation of the transmission paths 20. The division of the n codeword bits into six groups G1 to G6 is indicated on the left-hand side in FIG. 2.

A first group G1 contains the ten bits A0:9, which are relevant for the instructions MRS, ACT, WRD, and RDD. Thus, for the switching bit S1 that activates the transmission paths of the bit group A0:9 by its binary value “1”, the following logic applies:

S1=1, if: (MRS or ACT or WRD or RDD).

Expressed as a table by codeword bits of the subset K defined above:

S1 = 1, if

| | | | | |
|---|---|---|---|---|
| CS | 1 | 1 | 1 | 1 |
| RAS | 1 | 1 | 0 | 0 |
| CAS | 1 | 0 | 1 | 1 |
| WE | 1 | 0 | 1 | 0 |

A second group G2 contains the single bit A10, which is only relevant for the instructions MRS, ACT, WRD, RDD, and PRE. Thus, the following logic applies to the switching bit S2

S2=1, if: (MRS or ACT or WRD or RDD or PRE).

Expressed as a table by codeword bits of the subset K defined above:

S2 = 1, if

| | | | | | |
|---|---|---|---|---|---|
| CS | 1 | 1 | 1 | 1 | 1 |
| RAS | 1 | 1 | 0 | 0 | 1 |
| CAS | 1 | 0 | 1 | 1 | 0 |
| WE | 1 | 0 | 1 | 0 | 1 |

A third group G3 contains the five bits A11:A15, which are only relevant for the instructions MRS and ACT. Thus, the following logic applies to the switching bit S3

S3=1, if: (MRS or ACT).

Expressed as a table by codeword bits of the subset K defined above:

S3 = 1, if

| | | |
|---|---|---|
| CS | 1 | 1 |
| RAS | 1 | 1 |
| CAS | 1 | 0 |
| WE | 1 | 0 |

A fourth group G4 contains the two bits BA0:1, which are only relevant for the instructions MRS, ACT, WRD, RDD, and PRE. Thus the following logic applies to the switching bit S4

S4=1, if: (MRS or ACT or WRD or RDD or PRE with A10=0).

Expressed as a table by codeword bits of the subset K defined above:

S4 = 1, if

| | | | | | |
|---|---|---|---|---|---|
| CS | 1 | 1 | 1 | 1 | 1 |
| RAS | 1 | 1 | 0 | 0 | 1 |
| CAS | 1 | 0 | 1 | 1 | 0 |
| WE | 1 | 0 | 1 | 0 | 1 |
| A10 | 0 | 0 | 0 | 0 | 0 |

A fifth group G5 contains the three bits RAS, CAS, WE, which are relevant for the instructions MRS, ARF, ACT, WRD, RDD, PRE, BST, NOP, i.e., for all instructions except for DES. Thus the following logic applies to the switching bit S5

S5=1, if: (MRS or ARF or ACT or WRD or RDD or PRE or BST or NOP); or if: (not DES).

Expressed as a table by codeword bits of the subset K defined above:

S5 = 1, if

| | |
|---|---|
| CS | 1 |

A sixth group G6 contains the single bit CS, which is relevant for all instructions. The switching bit S6 is therefore always “1”.

The binary values of the switching bits S1:S6 for the different instructions are entered in the lower section of the table in FIG. 2.

The selection device 30 shown in FIG. 1 may use only the k=5 codeword bits of the subset K, i.e., just the bits CS, RAS, CAS, WE, A10, in order to set selectively the binary values for the g-1=5 switching bits S1:5 (the switching bit S6 remains constantly at “1” of course). This selection function can be fulfilled by a ROM having relatively few binary storage locations, or by a relatively low complexity logic-gate circuit. A further simplification is possible by deriving the switching bit S5 directly from the terminal X[CS] of the codeword source 10, as indicated by the dashed line in FIG. 1. This is possible because S5 has the same binary value as the codeword bit CS in the example described herein. In this alternative, the selection device may set just 4 switching bits selectively.

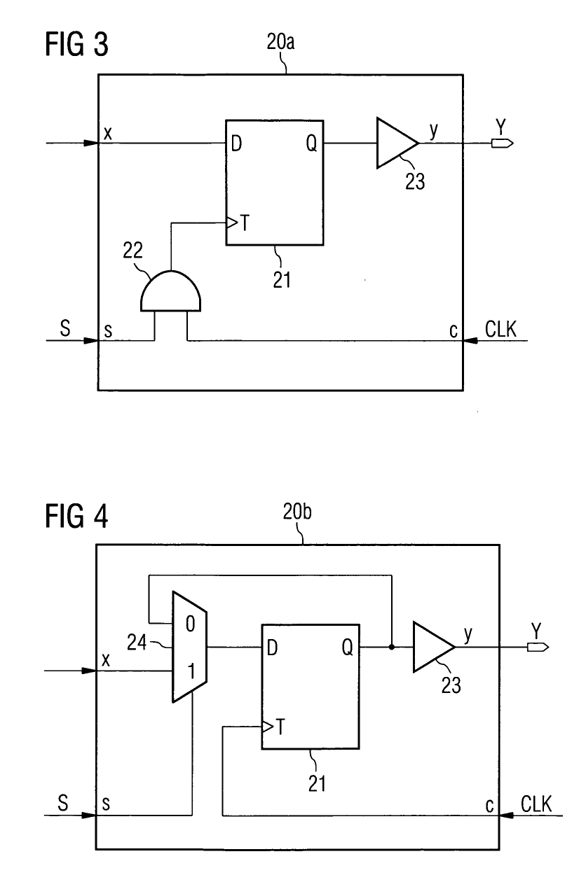

Thus, one may not utilize any switching device at all in the transmission path 20 of the codeword bit CS for selective deactivation, because the bit CS is relevant, and so the path may remain active. In one embodiment, however, all transmission paths may have the same design in order to keep the delays equal and thus ensure the synchronicity of the transmission. The transmission path 20a shown in FIG. 3 has an input X for the codeword bit from the assigned X output of the codeword source 10 (FIG. 1), a control input s for the assigned switching bit S, a clock terminal c for receiving the clock signal CLK, and the output y leading to the assigned transmit terminal Y. The transmission path 20a contains a transmit driver 23 as output stage. Connected to the input of the driver 23 is a D-flip-flop (data flip-flop) 21 whose data input D receives the codeword bit, and whose clock input T is connected to the output of a two-input AND gate 22. The first input of the AND gate 22 receives the clock signal CLK, and its second input receives the switching bit S. With every active clock edge (“0” to “1” transition) that reaches the clock input of the flip-flop 21, the flip-flop 21 is set to that state given by the binary value of the codeword bit at the D input. When the switching bit S has the logic value “1”, the AND gate 22 transfers the clock edges to the flip-flop 21, so that its Q-output produces at the input of the transmit driver 23 the logic value of the current codeword bit, and the transmit driver 23 takes the transmit terminal Y to the level corresponding to this logic value. When the switching bit S has the value “0”, the output of the AND gate 22 stays at “0”, so that the clock signal remains inactive and the flip-flop 22 retains its previous state. Since no change occurs at the input to the transmit driver 23, this driver 23 is not modulated and thus consumes no power in changing the transmit level at the terminal Y.

The embodiment 20b of the transmission paths 20 shown in FIG. 4 differs from the embodiment shown in FIG. 3 in that the “freezing” of the transmit bits is performed by a feedback that selectively latches the flip-flop 21. The clock signal CLK is applied continuously to the clock input T of the flip-flop 21, while the data input D receives via a multiplexer 24 controlled by the switching bit S either the assigned codeword bit or the signal from the Q-output of the flip-flop. When S=“1”, the D-input receives the codeword bit, so that at every active clock edge, the flip-flop 21 assumes the state given by the binary value of the codeword bit, and modulates the transmit driver 23 accordingly. When S=“0”, the D-input receives the logic value of the Q-output, so that the flip-flop 21 retains its previous state and the input signal to the transmit driver 23 remains unchanged.

In order to take into account delay differences between the codeword bits and the clock signal CLK, and also to ensure the correct phase relation between the codeword bits and the clock signal CLK in the transmission paths 20, equalization delays may be incorporated, symbolized by the block 50 in FIG. 1.

The code driver described above with reference to the drawing figures, which is designed for use in a memory controller having a specific instruction structure, is, as stated, only an example of a possible implementation form of the invention. The principles described may also be transferred directly to other instruction structures by designing or programming the selection device to implement the appropriate logic function for the particular case. Since the instruction structure itself implicitly contains the information as to which codeword bits are relevant to which instruction, the selection device can also be designed so that it derives the switching bits S for the selective activation of the transmission paths 20 from the instructions yet to be coded, i.e., at a point prior to the codeword source 10.

In addition, the invention is not restricted to use in memory controllers, but can be applied wherever sequences of messages as sequences of codewords of fixed number of digits n are to be sent to a receiver that does not always use the contents of all n codeword digits in order to “interpret” a message. In addition, the invention is not restricted to codewords having 2-valued (binary) characters. The codeword characters can also come from a repertoire of more than two character values. The transmit-modulation power consumption is also reduced in this case if no modulation takes place for those codeword digits irrelevant at a given time.

While the foregoing is directed to embodiments of the present invention, other and further embodiments of the invention may be devised without departing from the basic scope thereof, and the scope thereof is determined by the claims that follow.

What is claimed is:

1. A code driver comprising:
a codeword source comprising n >1 source terminals, wherein the codeword source is configured to output at the terminals a sequence of n-digit codewords, each in the form of n codeword digits,
n transmit terminals for sending the message represented by the codewords to a receiver;
n parallel transmission paths between the n source terminals and the n transmit terminals;
a selection device configured to:
indicate, for each codeword, which of the n digits of the codeword concerned are relevant digits to decoding of the message in the receiver; and
depending on the indication, activate only the n transmission paths that are assigned to the relevant digits of the codeword.

2. The code driver of claim 1, wherein the indication of which of the n digits of the codewords are relevant is contained in a subset of the codeword digits, and wherein
the selection device decodes the subset of the codeword digits to determine which of the n digits of the codewords are relevant.

3. The code driver of claim 1, wherein the selection device divides the n codeword digits into g different groups, wherein each of the elements in each of the groups are relevant or irrelevant simultaneously, and wherein the selection device is configured to:
generate, for each transmission path corresponding to each codeword digit of one of the g different groups, a common switching signal for switching the transmission path.

4. The coder driver claim 1, wherein
each transmission path contains a transmit driver connected to the associated transmit terminal.

5. The code driver of claim 4, wherein each transmission path which is assigned to a corresponding codeword digit which may be irrelevant to the receiver contains a latching device, which, in the inactive state of the transmission path, holds a state of the transmit driver unchanged.

6. The code driver of claim 5, wherein the latching device comprises:
a data flip-flop comprising:
a data input connected to receive the corresponding codeword digit for the transmission path;
an output connected to an input of the transmit driver; and
a clock input which receives a clock signal used to clock the corresponding codeword digit, wherein the selection device only applies the corresponding codeword digit when the corresponding codeword digit is relevant.

7. The code driver of claim 6, wherein the latching device comprises:
a data flip-flop comprising:
an output connected to an input of the transmit driver;
a clock input which receives a clock signal used to clock the corresponding codeword digit;
a data input; and
a multiplexer, wherein the multiplexer applies the corresponding codeword digit to the data input when the corresponding codeword digit is relevant, and wherein the multiplexer connects the output to the data input when the corresponding codeword digit is irrelevant.

8. The code driver of claim 2, wherein the selection device decodes from one or more of the n codeword digits an indication of relevant n codeword digits.

9. A method of transmitting an instruction across a parallel interface having multiple transmission paths:
determining whether bits of the instruction are used to process the instruction by a receiver of the instruction; and
for each bit used to process the instruction, activating a respective transmission path corresponding to the bit used to process the instruction without activating respective transmission paths corresponding to those bits not used to process the instruction, thereby driving only those bits used to process the instruction across the respective transmission paths.

10. The method of claim 9, further comprising, for each bit not used to process the instruction, deactivating the respective transmission paths corresponding to the bit not used, wherein deactivating the transmission path corresponding to the bit not used to process the instruction comprises maintaining a previous value driven across the transmission path.

11. The method of claim 9, wherein determining whether bits of the instruction are used to process the instruction comprises, for at least one bit:
determining a value of one or more other bits of the instruction; and
based on the value of the one or more other bits of the instruction, determining whether the at least one bit of the instruction is used to process the instruction.

12. The method of claim 9, wherein determining whether bits of the instruction are used to process the instruction comprises:
grouping at least two bits of the instruction, wherein every bit of the grouping is either used or not used to process any given instruction;
determining a value of one or more bits of the instruction which are not in the grouping; and
based on the value of the one or more bits of the instruction which are not in the grouping, determining whether the at least two bits of the grouping are used to process the instruction.

13. The method of claim 9, wherein, for each instruction, a first group of bits of the instruction are used to determine whether each bit in a second group of bits of the instruction are used for processing, and, if not, transmission paths corresponding to the second group of bits of the instruction are deactivated.

14. A memory controller comprising:
a parallel interface for transmitting instructions, the parallel interface comprising a plurality of transmission paths, each transmission path corresponding to a bit of an instruction;
control circuitry configured to transmit an instruction by:
determining whether bits of the instruction are used to process the instruction by a receiver of the instruction; and
for each bit used to process the instruction, activating a respective transmission path corresponding to the bit used to process the instruction without activating respective transmission paths corresponding to those bits not used to process the instruction thereby driving only those bits used to process the instruction across the respective transmission paths.

15. The memory controller of claim 14, further comprising, for each bit not used to process the instruction, deactivating the respective transmission paths corresponding to the bit not used, wherein deactivating the transmission path corresponding to the bit not used to process the instruction comprises maintaining a previous value driven across the transmission path.

16. The memory controller of claim 14, wherein determining whether bits of the instruction are used to process the instruction comprises, for at least one bit:
determining a value of one or more other bits of the instruction; and
based on the value of the one or more other bits of the instruction, determining whether the at least one bit of the instruction is used to process the instruction.

17. The memory controller of claim 14, wherein determining whether bits of the instruction are used to process the instruction comprises:
grouping at least two bits of the instruction, wherein every bit of the grouping is either used or not used to process any given instruction;
determining a value of one or more bits of the instruction which are not in the grouping; and
based on the value of the one or more bits of the instruction which are not in the grouping, determining whether the at least two bits of the grouping are used to process the instruction.

18. The memory controller of claim 14, wherein, for each instruction transmitted, a first group of bits of the instruction are used to determine whether each bit in a second group of bits of the instruction are used for processing, and, if not, transmission paths corresponding to the second group of bits of the instruction are deactivated.

19. A memory controller comprising:
means for parallel interfacing configured to transmit instructions, the means for parallel interfacing comprising a plurality of means for transmitting, each means for transmitting corresponding to a bit of an instruction;
means for controlling configured to transmit an instruction by:
determining whether bits of the instruction are used to process the instruction by a receiver of the instruction; and
for each bit used to process the instruction, activating a respective means for transmitting corresponding to the bit used to process the instruction without activating respective transmission paths corresponding to those bits not used to process the instruction thereby driving only those bits used to process the instruction across the respective means for transmitting.

20. The memory controller of claim 19, further comprising, for each bit not used to process the instruction, deactivating the respective transmission paths corresponding to the bit not used, wherein deactivating the means for transmitting corresponding to the bit not used to process the instruction comprises maintaining a previous value driven across the means for transmitting.

21. The memory controller of claim 19, wherein determining whether bits of the instruction are used to process the instruction comprises, for at least one bit:
determining a value of one or more other bits of the instruction; and
based on the value of the one or more other bits of the instruction, determining whether the at least one bit of the instruction is used to process the instruction.

22. The memory controller of claim 19, wherein determining whether bits of the instruction are used to process the instruction comprises:
grouping at least two bits of the instruction, wherein every bit of the grouping is either used or not used to process any given instruction;
determining a value of one or more bits of the instruction which are not in the grouping; and
based on the value of the one or more bits of the instruction which are not in the grouping, determining whether the at least two bits of the grouping are used to process the instruction.

23. The memory controller of claim 19, wherein, for each instruction transmitted, a first group of bits of the instruction are used to determine whether each bit in a second group of bits of the instruction are used for processing, and, if not, each means for transmitting corresponding to the second group of bits of the instruction are deactivated.

23. A memory controller comprising:
instruction circuitry configured to generate an instruction;
parallel transmission circuitry configured to transmit bits of the instruction, wherein each bit of the instruction is transmitted across a respective transmission path;
selection circuitry configured to:
receive one or more first bits of the instruction;
based on the one or more first bits of the instruction, determine whether one or more second bits of the instruction are used to process the instruction by a receiver of the instruction;
generate one more selection signals, wherein the selection signals activate only the respective transmission paths for the one or more second bits of the instruction which are used to process the instruction.

24. The memory controller of claim 23, wherein the selection circuitry comprises a memory, wherein the one or more first bits of the instruction are used to access the memory, and wherein the selection signals are output by the memory.

25. The memory controller of claim 24, wherein the memory is programmable according to a plurality of possible instruction sets transmitted by the memory controller.

26. The memory controller of claim 23, wherein each respective transmission path comprises a driver circuit, wherein the driver circuit comprises:
a D flip-flop, wherein a data input of the D flip-flop is one bit of the instruction and a data output of the D flip-flop is used to transmit the one bit; and
an AND gate, a first input of which is one of the one or more selection signals and a second input of which is a clock signal, wherein the output of the AND gate is connected to the D flip-flip such that the D flip-flop latches the one bit only when a clock signal is received and when the one of the one or more selection signals is asserted by the selection circuitry.

27. The memory controller of claim 23, wherein each respective transmission path comprises a driver circuit, wherein the driver circuit comprises:
a D flip-flop; and
a multiplexer comprising:
a first input comprising one bit of the instruction;
a second input connected to the output of the D flip-flop;
an output connected to an input of the D flip-flop; and
a control input connected to one of the one or more selection signals, wherein the output of the D flip-flop is maintained as the input of the D flip-flop when the selection signal is lowered, and wherein the one bit is connected to the input to the D flip-flop when the selection signal is asserted.
